(19) United States
(12) Patent Application Publication
(10) Pub. No.: US 2019/0384156 A1
(43) Pub. Date: Dec. 19, 2019

(54) REFLECTIVE MASK BLANK, REFLECTIVE MASK, AND METHOD OF MANUFACTURING REFLECTIVE MASK BLANK

(71) Applicant: AGC Inc., Chiyoda-ku (JP)

(72) Inventor: Hiroyoshi TANABE, Tokyo (JP)

(73) Assignee: AGC Inc., Chiyoda-ku (JP)

(21) Appl. No.: 16/432,499

(22) Filed: Jun. 5, 2019

(30) Foreign Application Priority Data
Jun. 13, 2018 (JP) 2018-112601
May 13, 2019 (JP) 2019-090435

(51) Int. Cl. G03F 1/24; G03F 1/54; G03F 1/80

(52) U.S. Cl. CPC G03F 1/24; G03F 1/80; G03F 1/54

(57) ABSTRACT

A reflective mask blank has a reflective layer to reflect EUV light and an absorber layer to absorb the EUV light, formed over a substrate in this order from a substrate side. The absorber layer contains Sn, and a preventive layer is provided over the absorber layer, to prevent oxidation of the absorber layer.

### CROSS-REFERENCE TO RELATED APPLICATIONS

The present application is based upon and claims the benefit of priority to Japanese Patent Application No. 2018-112601 filed on Jun. 13, 2018, and Japanese Patent Application No. 2019-090435 filed on May 13, 2019, the entire contents of which are hereby incorporated by reference.

### BACKGROUND OF THE INVENTION

### 1. Field of the Invention

The present disclosure relates to a reflective mask blank, a reflective mask, and a method of manufacturing a reflective mask blank.

### 2. Description of the Related Art

In recent years, as finer microfabrication of integrated circuits that constitute semiconductor devices advances, extreme ultraviolet (EUV) lithography has been studied as an alternative to conventional exposure techniques using visible light, ultraviolet light (wavelength of 193 to 365 nm), ArF excimer laser light (wavelength 193 nm), and the like.

In EUV lithography, as the light source for exposure, EUV light having a shorter wavelength than ArF excimer laser light is used. Note that EUV light refers to light having a wavelength in the soft X-ray region or the vacuum ultraviolet region, in particular, light having a wavelength of approximately 0.2 to 100 nm. For example, EUV light having a wavelength of approximately 13.5 nm is used as the EUV light.

Since EUV light is easily absorbed by any material, refractive optical systems used in conventional exposure techniques cannot be used. Therefore, reflective optical systems such as reflective masks and mirrors are used in EUV lithography. In EUV lithography, a reflective mask is used as a pattern transfer mask.

A reflective mask has a reflective layer formed over a substrate to reflect EUV light, and over the reflective layer, has a patterned absorber layer to absorb the EUV light. The reflective mask is obtained by using, as a primitive plate, a reflective mask blank constituted with a reflective layer and an absorber layer layered over the substrate in this order from the substrate side; removing part of the absorber layer to form a predetermined pattern; and then, cleaning the patterned mask with a cleaning solution.

The EUV light incident on the reflective mask is absorbed by the absorber layer and reflected by the reflective layer. The reflected EUV light forms an image on the surface of an exposure material (resist-coated wafer) by an optical system. This imaging transfers the pattern of the absorber layer onto the surface of the exposure material.

In EUV lithography, EUV light is normally incident on a reflective mask from a direction tilted by approximately 6° and is reflected obliquely in the same way. Therefore, if the film thickness of the absorber layer is too thick, the light path of the EUV light may be shielded (shadowing). Due to an influence of shadowing, if the substrate or the like becomes to have a part on which a shadow of the absorber layer is cast, the pattern of the reflective mask may not be faithfully transferred onto the surface of the exposure material, and precision of the pattern may be impaired. On the other hand, if the film thickness of the absorber layer is made thinner, the light shielding performance of the EUV light in the reflective mask becomes lower, and the reflectance of the EUV light becomes higher. Therefore, there is a likelihood that the contrast between the patterned part and the rest of the reflective mask becomes lower.

Thereupon, reflective mask blanks have been studied that make it possible to faithfully transfer the pattern of a reflective mask, and at the same time, to control reduction of the contrast. For example, Japanese Laid-open Patent Publication No. 2007-273678 (Patent Document 1) describes a reflective mask blank in which the absorber film is constituted with a material that contains Ta as the main component by 50 atomic percent (at %) or more and further contains at least one species of element selected from among Te, Sb, Pt, I, Bi, Ir, Os, W, Re, Sn, In, Po, Fe, Au, Hg, Ga, and Al.

However, in the reflective mask blank described in Patent Document 1, there is a likelihood that the surface of the absorber film is oxidized to generate fine particles on the surface of the absorber film, and thereby, to generate defects on the surface of the absorber film. For example, in the case of forming the absorber film of an alloy of Ta and Sn, the surface of the absorber film may be oxidized to generate fine particles of a tin oxide on the surface of the absorber film. When producing a reflective mask, if fine particles are present at a location where the absorber film is to be etched by dry-etching, this part may not be etched to cause pattern defects at which the absorber film remains. In this case, when a wafer is exposed, the pattern defects on the reflective mask are transferred to the exposure material (resist) coated on the wafer, which is undesirable.

### SUMMARY OF THE INVENTION

One aspect of a reflective mask blank according to the present disclosure has a reflective layer to reflect EUV light and an absorber layer to absorb the EUV light, formed over a substrate in this order from a substrate side. The absorber layer contains Sn, and a preventive layer is provided over the absorber layer, to prevent oxidation of the absorber layer.

### BRIEF DESCRIPTION OF DRAWINGS

FIG. 1 is a schematic cross-sectional view of a reflective mask blank according to a first embodiment;

FIG. 2 is a flow chart illustrating an example of a method of manufacturing a reflective mask blank;

FIG. 3 is a schematic cross-sectional view illustrating an example of another form of a reflective mask blank;

FIG. 4 is a schematic cross-sectional view illustrating an example of yet another form of a reflective mask blank;

FIG. 5 is a schematic cross-sectional view illustrating an example of a configuration of a reflective mask;

FIGS. 6A to 6C are diagrams illustrating a manufacturing process of a reflective mask;

FIG. 7 is a schematic cross-sectional view of a reflective mask blank according to a second embodiment;

FIG. 8 is a schematic cross-sectional view illustrating an example of another form of a reflective mask blank;

FIG. 9 is a schematic cross-sectional view of a reflective mask blank of Comparative Example 1;

FIG. 10 is a diagram illustrating a result of observation of the surface of the absorber layer of a reflective mask blank of Comparative Example 1;

FIG. 11 is a diagram illustrating a result of observation of the surface of the absorber layer of a reflective mask blank of Application Example 1; and

FIG. 12 is a diagram illustrating a result of observation of the surface of the absorber layer of a reflective mask blank of Application Example 2.

### DESCRIPTION OF THE PREFERRED EMBODIMENTS

In the following, embodiments will be described in detail.

According to one embodiment in the present disclosure, it is possible to provide a reflective mask blank that can control generation of defects on the surface of the absorber layer caused by oxidization of the surface of the absorber layer.

Note that in order to make the description easy to understand, the same elements throughout the drawings are assigned the same reference codes, to omit duplicated description. Also, the scale of a member in the drawings may differ from an actual scale. In the present specification, a three-dimensional orthogonal coordinate system having triaxial directions (X-axis direction, Y-axis direction, and Z-axis direction) is used, in which the coordinates on the principal surface of a substrate are represented in the X-axis direction and the Y-axis direction, and the height direction (thickness direction) is represented in the Z-axis direction. A direction directed from the bottom to the top of the substrate (the direction from the principal surface of the substrate toward the reflective layer) is denoted as the +Z-axis direction, and the opposite direction is denoted as the −Z-axis direction. In the following description, the +Z-axis direction may be referred to as “upward” and the −Z-axis direction may be referred to as “downward”. In the present specification, a numerical range presented in a form of “first numerical value to second numerical value” means that the first and second numerical values are included as the lower limit and the upper limit of the range, unless otherwise specified.

<Reflective Mask Blank>

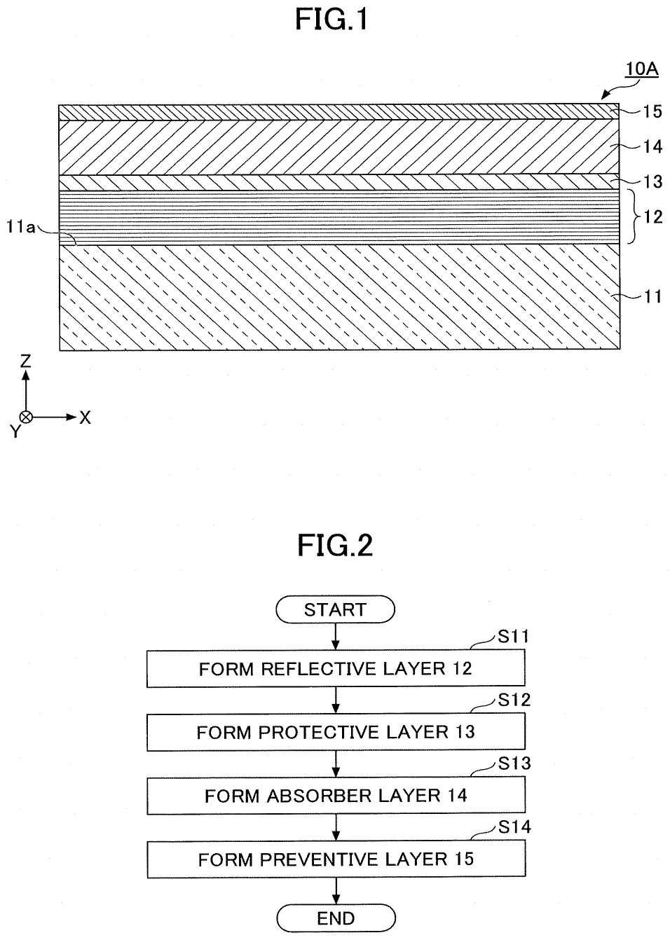

A reflective mask blank according to a first embodiment will be described. FIG. 1 is a schematic cross-sectional view of a reflective mask blank according to the first embodiment. As illustrated in FIG. 1, the reflective mask blank 10A is formed by layering over a substrate 11, a reflective layer 12, a protective layer 13, an absorber layer 14, and a preventive layer 15 in this order.

(Substrate)

It is favorable for the substrate 11 to have a low thermal expansion coefficient. A lower thermal expansion coefficient of the substrate 11 enables to better control distortion of a pattern formed in the absorber layer 14 due to heat generated when exposed to EUV light. Specifically, the thermal expansion coefficient of the substrate 11 is favorably 0±1.0×10⁻⁷/° C. at 20° C., and more favorably 0±0.3×10⁻⁷/° C. at 20° C.

As such a material having a low thermal expansion coefficient, for example, SiO₂—TiO₂-based glass or the like may be used. As the SiO₂—TiO₂-based glass, it is favorable to use a silica glass that contains 90 to 95 mass % of SiO₂ and 5 to 10 mass % of TiO₂. When the TiO₂ content is 5 to 10 mass %, the linear expansion coefficient around room temperature is approximately zero, and virtually no dimensional change occurs around room temperature. Note that the SiO₂—TiO₂-based glass may contain a minute amount of components other than SiO₂ and TiO₂.

It is favorable for the first principal surface 11a of the substrate 11 on which the reflective layer 12 is layered, to have a high smoothness. The smoothness of the first principal surface 11a can be evaluated by the surface roughness, which is obtained by measurement using an atomic force microscope. The surface roughness of the first principal surface 11a is favorably less than or equal to 0.15 nm in terms of the root-mean-square roughness Rq.

It is favorable to apply surface finishing to the first principal surface 11a so as to have a predetermined flatness. This is for obtaining a reflective mask with high precision of pattern transfer and precision of positions. In a predetermined area (e.g., an area of 132 mm×132 mm) of the first principal surface 11a of the substrate 11, the flatness is favorably less than or equal to 100 nm, more favorably less than or equal to 50 nm, and even more favorably less than or equal to 30 nm.

Also, it is favorable for the substrate 11 to have resistance to a cleaning liquid that is used for cleaning a reflective mask blank, a reflective mask blank having a pattern formed, or a reflective mask.

Furthermore, it is favorable for the substrate 11 to have a high rigidity in order to prevent deformation of films formed over the substrate 11 (the reflective layer 12, etc.) due to film stress. For example, it is favorable for the substrate 11 to have a high Young's modulus greater than or equal to 65 GPa.

The size, thickness, and the like of the substrate 11 are properly determined in accordance with design values and the like of the reflective mask.

The first principal surface 11a of the substrate 11 is formed to have a rectangular or circular shape in plan view. In the present specification, rectangular shapes include rectangles, squares, and in addition, a shape formed by rounding corners of a rectangle or square.

(Reflective Layer)

The reflective layer 12 has a high reflectance with respect to EUV light. Specifically, when EUV light is incident on the surface of the reflective layer 12 at an angle of incidence of 6°, the maximum value of the reflectance of EUV light having a wavelength around 13.5 nm is favorably greater than or equal to 60%, and more favorably greater than or equal to 65%. Also, in the case of the reflective layer 12 over which the protective layer 13 and the absorber layer 14 are layered, similarly, the maximum value of the reflectance of the EUV light having a wavelength around 13.5 nm is favorably greater than or equal to 60%, and more favorably greater than or equal to 65%.

The reflective layer 12 is a multilayer film in which layers containing respective elements with different refractive indices as main components are layered cyclically. As the reflective layer 12, in general, a multilayer reflective film is used in which high-refractive-index layers that exhibit a high refractive index with respect to EUV light and low-refractive-index layers that exhibit a low refractive index with respect to the EUV light are alternately layered from the substrate 11 side.

The multilayer reflective film has multiple cycles of layered structures where one cycle may have a high-refractive-index layer and a low-refractive-index layer layered in this order from the substrate 11 side, or one cycle may have a low-refractive-index layer and a high-refractive-index layer layered in this order from the substrate 11 side. Note that in either case, it is favorable for the multilayer reflective film to have a high-refractive-index layer as the topmost surface layer (the topmost layer). This is because a low-refractive-index layer is easily oxidized, and hence, if a low-refractive-index layer comes as the topmost layer of the reflective layer 12, there is a likelihood that the reflectance of the reflective layer 12 decreases.

As a high-refractive-index layer, a layer containing Si can be used. As a material containing Si, other than Si simple substance, an Si compound containing one or more species selected from among a group consisting of B, C, N, and O can be used. Using such a high-refractive-index layer containing Si enables to produce a reflective mask having an excellent reflectance for EUV light. As a material for a low-refractive-index layer, a metal selected from among a group consisting of Mo, Ru, Rh, and Pt, or an alloy of these may be used. In the present embodiment, it is favorable that the low-refractive-index layer is a layer containing Mo and the high-refractive-index layer is a layer containing Si. Note that in this case, by having a high-refractive-index layer (a layer containing Si) as the topmost layer of the reflective layer 12, a silicon oxide layer containing Si and O is formed between the topmost layer (the layer containing Si) and the protective layer 13, which improves the cleaning resistance of the reflective mask.

Although the reflective layer 12 includes multiple high-refractive-index layers and multiple low-refractive-index layers, the film thickness may not be necessarily uniform among the high-refractive-index layers or among the low-refractive-index layers.

The film thickness and the number of cycles of the layers constituting the reflective layer 12 may be appropriately selected depending on film materials to be used; the reflectance of EUV light required for the reflective layer 12; the wavelength of the EUV light (exposure wavelength); and/or the like. For example, in the case of setting the maximum value of the reflectance of the reflective layer 12 for EUV light having a wavelength around 13.5 nm to be greater than or equal to 60%, an Mo/Si-multilayer reflection film that has a low-refractive-index layer (a layer containing Mo) and a high-refractive-index layer (a layer containing Si) alternately layered for 30 to 60 cycles, is favorably used.

Note that each of the layers constituting the reflective layer 12 can be formed as a film having a desired film thickness by using a publicly known film-forming method such as magnetron sputtering or ion beam sputtering. For example, in the case of producing the reflective layer 12 by using ion beam sputtering, it is performed by supplying particles of ions from ion sources to a target of a high-refractive-index material and a target of a low-refractive-index material. In the case of forming the reflective layer 12 as an Mo/Si-multilayer reflective film, for example, first, a layer containing Si and having a predetermined film thickness is formed over the substrate 11 by ion beam sputtering using an Si target. Then, using an Mo target, a layer containing Mo and having a predetermined film thickness is formed. Counting this pair of Si-containing layer and Mo-containing layer as one cycle, by layering these layers for 30 to 60 cycles, an Mo/Si-multilayer reflective film is formed.

(Protective Layer)

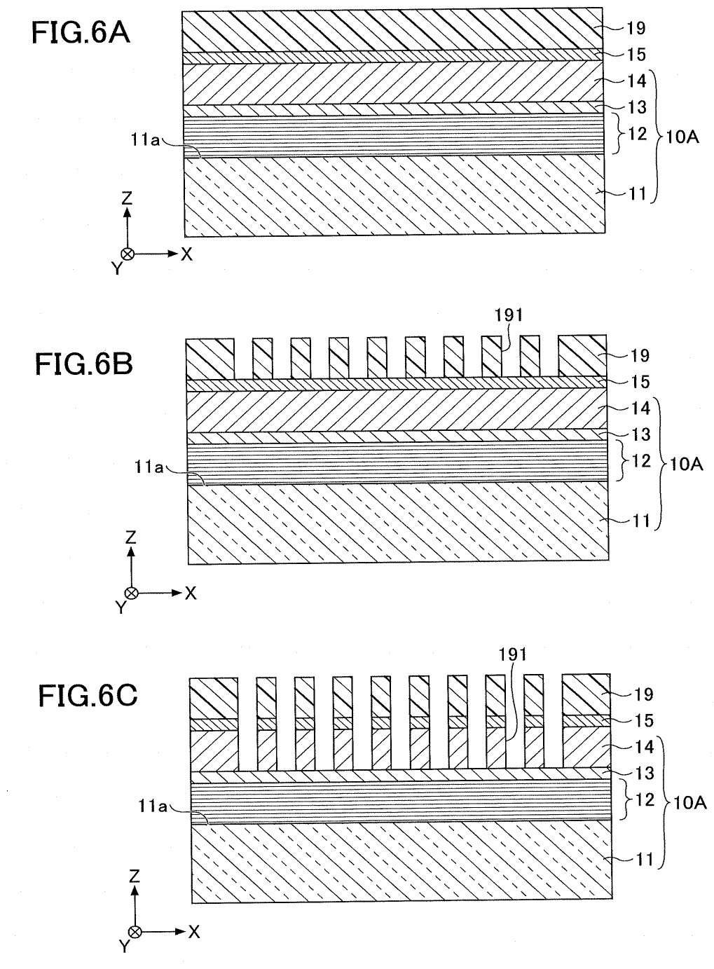

When etching (normally, dry-etching) the absorber layer 14 to form an absorber pattern 141 (see FIG. 5) in the absorber layer 14 in the course of manufacturing a reflective mask 20 (see FIG. 5), which will be described later, the protective layer 13 prevents the surface of the reflective layer 12 from being damaged by etching, to protect the reflective layer 12. The protective layer 13 also protects the reflective layer 12 from a cleaning liquid that is used for stripping a resist layer 19 (see FIGS. 6A to 6C) that remains on the reflective mask blank having been etched, to clean the reflective mask blank. Therefore, the reflectance of the obtained reflective mask 20 (see FIG. 5) with respect to EUV light becomes satisfactory.

Although FIG. 1 illustrates a case where the protective layer 13 has a single layer, the protective layer 13 may have multiple layers.

As the material to form the protective layer 13, a substance that is hardly damaged by etching when etching the absorber layer 14 is selected. As substances that satisfy this condition, for example, Ru as a metal simple substance; Ru alloys containing one or more species of metals selected from among a group consisting of B, Si, Ti, Nb, Mo, Zr, Y, La, Co, and Re; Ru-based materials including a nitride or the like containing nitrogen in an Ru alloy; Cr, Al, Ta, and nitrides of these containing nitrogen; SiO₂, Si₃N₄, Al₂O₃, and mixtures of these; and the like, may be exemplified. Among these, Ru as a metal simple substance, Ru alloys, CrN, and SiO₂ are favorable. Ru as a metal simple substance and Ru alloys are particularly favorable because these are hardly etched with an oxygen-free gas, and functions as an etching stopper when processing a reflective mask.

In the case of forming the protective layer 13 of an Ru alloy, the Ru content in the Ru alloy is favorably greater than or equal to 95 at % and less than 100 at %. As long as the Ru content falls within the above range, in the case of the reflective layer 12 being an Mo/Si-multilayer reflective film, it is possible to prevent Si from diffusing from an Si layer of the reflective layer 12 into the protective layer 13. Also, the protective layer 13 can function as expected as an etching stopper when applying an etching process to the absorber layer 14 while sufficiently securing the reflectance of EUV light. Further, the protective layer 13 enables the reflective mask to have resistance to cleaning, and can prevent the reflective layer 12 from degrading over time.

The film thickness of the protective layer 13 is not limited in particular as long as the protective layer 13 can function as expected. From the viewpoint of maintaining the reflectance of EUV light reflected on the reflective layer 12, the film thickness of the protective layer 13 is favorably greater than or equal to 1 nm, more favorably greater than or equal to 1.5 nm, and furthermore favorably greater than or equal to 2 nm. The film thickness of the protective layer 13 is favorably less than or equal to 8 nm, more favorably less than or equal to 6 nm, and furthermore favorably less than or equal to 5 nm.

As the method of forming the protective layer 13, a publicly known film-forming method may be used, such as magnetron sputtering or ion beam sputtering.

(Absorber Layer)

In order to be used in a reflective mask for EUV lithography, the absorber layer 14 needs to have properties including a high absorption coefficient of EUV light; easiness of etching; and a high resistance to a cleaning liquid.

The absorber layer 14 absorbs EUV light and has an extremely low reflectance of EUV light. Specifically, when the surface of the absorber layer 14 is irradiated with EUV light, it is favorable that the maximum value of reflectance with respect to EUV light having a wavelength of around 13.5 nm is less than or equal to 2%, and more favorable to be less than or equal to 1%. Therefore, the absorber layer 14 needs to have a high absorption coefficient of EUV light.

Also, the absorber layer 14 is processed by etching, such as dry-etching using a chlorine (Cl) based gas, which may be Cl₂, SiCl₄, CHCl₃ or the like, or a fluorine (F) based gas, which may be CF₄ or CHF₃ or the like. Therefore, the absorber layer 14 needs to be easily etched.

Furthermore, in the course of manufacturing the reflective mask 20 (see FIG. 5), which will be described later, the absorber layer 14 is exposed to a cleaning liquid when the cleaning liquid is used for removing a resist pattern 191 (see FIGS. 6A to 6C) that remains on the reflective mask blank having been etched. At this time, as the cleaning liquid, a sulfuric acid-peroxide mixture (SPM), sulfuric acid, ammonia, an ammonia hydrogen peroxide mixture (APM), cleaning water containing hydroxyl radical, ozonized water, or the like may be used. In EUV lithography, SPM is commonly used as the cleaning liquid of resist. Note that SPM is a solution in which sulfuric acid and hydrogen peroxide are mixed, for example, a solution in which sulfuric acid and hydrogen peroxide are mixed by a volume ratio of 3:1. At this time, it is favorable to control the temperature of SPM to be 100° C. or higher from the viewpoint of improving the etching rate. Therefore, the absorber layer 14 needs to be highly resistant to the cleaning liquid. It is favorable for the absorber layer 14 to have a low etching rate (e.g., less than or equal to 0.10 nm/min.) when immersed in a solution at 100° C. of, for example, 75 vol % of sulfuric acid and 25 vol % of hydrogen peroxide.

In order to achieve the properties as described above, the absorber layer 14 contains Sn. Since Sn has a high absorption coefficient, the absorber layer 14 containing Sn can have a low reflectance. Also, the absorber layer 14 containing Sn can be easily etched with a Cl-based gas or the like.

It is favorable for the absorber layer 14 to contain Ta, Cr, and/or Ti in addition to Sn. One species of these elements may be added alone, or two or more species may be added to be contained. The absorber layer 14 further containing one or more species of these elements can have a higher cleaning resistance.

The absorber layer 14 may further contain N, B, Hf, and/or H in addition to Sn. One species of these elements may be added alone, or two or more species may be added to be contained. In particular, it is favorable for the absorber layer 14 to contain at least one of N and B from among these elements. Having at least one of N and B contained in the absorber layer 14 enables the absorber layer 14 to be amorphous or to have a microcrystalline structure in a crystalline state.

A favorable composition of the absorber layer 14 is, for example, SnTa, SnTaN, SnTaB, or SnTaBN.

It is favorable for the absorber layer 14 to be amorphous in a crystalline state. This enables the absorber layer 14 to have excellent smoothness and flatness. Also, improved smoothness and flatness of the absorber layer 14 makes the edge roughness of the absorber pattern 141 (see FIG. 5) smaller, and thereby, raises the dimensional precision of the absorber pattern 141 (see FIG. 5).

The absorber layer 14 may be a single layer film or a multilayer film constituted with multiple layers. In the case of the absorber layer 14 being a single layer film, the number of stages in the manufacturing process of the mask blank can be reduced, and the production efficiency can be improved. In the case of the absorber layer 14 being a multilayer film, by appropriately setting the optical constants and the film thickness of an upper layer in the absorber layer 14, the upper layer in the absorber layer 14 can be used as an antireflective film when inspecting the absorber pattern 141 (see FIG. 5) by using inspection light. This enables to improve the inspection sensitivity when inspecting the absorber pattern.

Although the film thickness of the absorber layer 14 can be appropriately designed according to the composition of the absorber layer 14 and the like, it is favorably thinner from the viewpoint of controlling the effect of shadowing. The film thickness of the absorber layer 14 is, for example, favorably less than or equal to 40 nm from the viewpoints of keeping the reflectance of the absorber layer 14 to be less than or equal to 1% and of obtaining a sufficient contrast. The film thickness of the absorber layer 14 is more favorably less than or equal to 35 nm, furthermore favorably less than or equal to 30 nm, even more favorably less than or equal to 25 nm, and particularly favorably less than or equal to 20 nm. The film thickness of the absorber layer 14 is determined depending on the reflectance, and a thinner film thickness is better. The film thickness of the absorber layer 14 can be measured, for example, by using X-ray reflectance (XRR), TEM, or the like.

The absorber layer 14 can be formed by using a publicly known film-forming method such as magnetron sputtering or ion beam sputtering. For example, in the case of forming an SnTa film as the absorber layer 14 by using magnetron sputtering, the absorber layer 14 can be formed by sputtering that uses a target including Sn and Ta, and Ar gas. The absorber layer 14 can also be formed by using co-sputtering that uses an Sn target and a Ta target simultaneously.

(Preventive Layer)

The preventive layer 15 is formed over the principal surface over the absorber layer 14 (in the +Z-axis direction).

As the material for forming the preventive layer 15, Ta, Ru, Cr, Ti, and/or Si may be used. One species of these elements may be contained alone or two or more species may be contained.

As the material of the preventive layer 15, Ta, Ru, Cr, Ti, Si, Ta nitride, Ru nitride, Ru nitride, Cr nitride, Ti nitride, Si nitride, Ta boride, Ru boride, Cr boride, Ti boride, Si boride, or Ta boron nitride may be used. One species of these elements may be contained alone or two or more species may be contained.

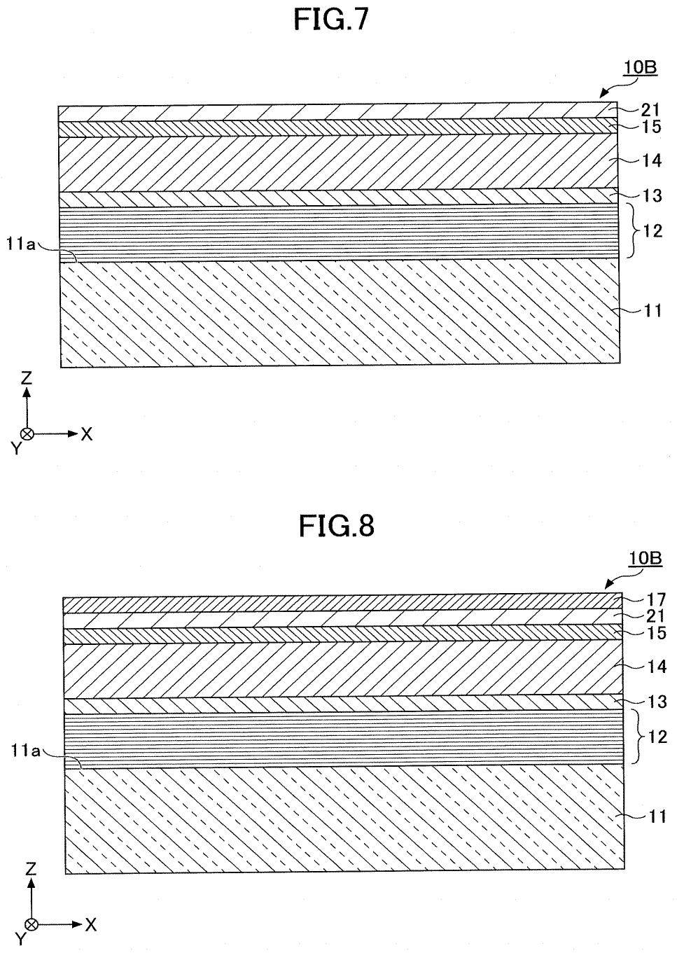

A favorable composition of the preventive layer 15 is, for example, Ta, TaN, TaB, or TaBN. For example, as will be described later, assume that a reflective mask blank 10B (see FIG. 7) according to a second embodiment having a stabilizing layer 21 over the preventive layer 15 is to be formed. In addition, assume that the stabilizing layer 21 contains an oxide, oxynitride, or oxyboride that contains Ta. In this case, if the preventive layer 15 is formed of one of these materials, the same target can be used when forming the preventive layer 15 and the stabilizing layer 21. Therefore, the required number of film-fouling chambers can be reduced, which is advantageous to the productivity of the reflective mask blank 10B (see FIG. 7).

The preventive layer 15 may further contain elements such as He, Ne, Ar, Kr, Xe, or the like.

The preventive layer 15 is a layer not containing Sn and oxygen. Here, “not containing Sn and oxygen” means that Sn and oxygen are not present on the surface and inside of the preventive layer 15 immediately after the preventive layer 15 has been formed. If the preventive layer 15 is exposed to an atmosphere containing oxygen, the surface on which the preventive layer 15 contacts oxygen may react with oxygen (may be oxidized) to form an oxide film on the surface of the preventive layer 15. At this time, if the preventive layer 15 contains Sn, there is a likelihood that Sn present on the surface of the preventive layer 15 reacts with oxygen to generate fine particles containing Sn, such as tin oxide on the surface of the preventive layer 15 as deposits; therefore, the preventive layer 15 does not contain Sn.

Note that “the preventive layer 15 not containing oxygen” means to exclude oxygen that would be contained in an oxide film that may be generated on the surface on which the preventive layer 15 contacts oxygen in a process after the preventive layer 15 has been formed. On the other hand, since the interface between the absorber layer 14 and the preventive layer 15 is not exposed to oxygen, oxygen is not contained around the interface between the preventive layer 15 and the absorber layer 14.

The preventive layer 15 can be formed in an inert gas atmosphere or in a gas atmosphere in which nitrogen is selectively added to an inert gas, by using a publicly known film-forming method such as magnetron sputtering or ion beam sputtering. For example, in the case of forming a Ta film, Ru film, Cr film, or Si film as the preventive layer 15 by using magnetron sputtering, a target containing Ta, Ru, Cr, or Si is used; and as the sputtering gas, an inert gas of He, Ar, Kr, or the like or a gas in which nitrogen is selectively added to an inert gas is used to form the preventive layer 15.

If the film thickness of the preventive layer 15 is too thick, etching of the preventive layer 15 takes a long time. Also, there is a likelihood that shadowing or the like becomes significant. On the other hand, if the preventive layer 15 is too thin, there is a likelihood that the function expected as the preventive layer 15 may not be exhibited stably and sufficiently. Therefore, the film thickness of the preventive layer 15 may be around several nm from the viewpoint of curbing the film thickness of the pattern of the reflective mask blank 10A, and favorably be less than or equal to 10 nm. The film thickness of the preventive layer 15 is more favorably less than or equal to 8 nm, furthermore favorably less than or equal to 6 nm, even more favorably less than or equal to 5 nm, and particularly favorably 4 nm. The film thickness of the preventive layer 15 is more favorably greater than or equal to 0.5 nm, furthermore favorably greater than or equal to 1 nm, even more favorably greater than or equal to 1.5 nm, and particularly favorably greater than or equal to 2 nm. The film thickness of the preventive layer 15 can be measured, for example, by using XRR, TEM, or the like.

As such, the reflective mask blank 10A has the preventive layer 15 over the absorber layer 14 that contains Sn. If the absorber layer 14 comes into contact with oxygen, there is a likelihood that part of Sn present on the surface of the absorber layer 14 reacts with oxygen to generate fine particles containing Sn made of a tin oxide or the like on the surface of the absorber layer 14 as deposits. As described above, the preventive layer 15 is formed as a film over the absorber layer 14 by using, as the sputtering gas, only an inert gas such as He, Ar, Kr, or the like or a gas in which nitrogen is selectively added to an inert gas. Therefore, forming the preventive layer 15 before the absorber layer 14 comes into contact with a gas containing oxygen and the like, enables to prevent the absorber layer 14 from contacting oxygen and the like. This further prevents oxidization of the surface of the absorber layer 14 and generation of deposits on the surface of the absorber layer 14, and enables to control generation of defects on the surface of the absorber layer 14.

Therefore, when producing a reflective mask 20 (see FIG. 5) by using the reflective mask blank 10A, it is possible to control generation of defects in the reflective mask 20 (see FIG. 5). As such, using the reflective mask blank 10A enables to stably form a defect-free pattern.

The reflective mask blank 10A may have the preventive layer 15 formed to contain one or more species of elements selected from among Ta, Ru, Cr, and Si. These elements can be easily dry-etched and have excellent cleaning resistance. Therefore, if the preventive layer 15 is configured to contain Ta and the like, even if the absorber layer 14 contains Sn, an absorber pattern 141 (see FIG. 5) that has a high cleaning resistance can be formed while preventing oxidation of the surface of the absorber layer 14.

The reflective mask blank 10A may have the preventive layer 15 formed by using Ta, Ru, Cr, Si, Ta nitride, Ru nitride, Cr nitride, Si nitride, Ta boride, Ru boride, Cr boride, Si boride or Ta boron nitride. Since these nitrides, borides, and a boron nitride are amorphous, it is possible to control the edge roughness of the absorber pattern 141 (see FIG. 5). Therefore, if configuring the preventive layer 15 to contain Ta nitride or the like, it is possible to prevent oxidation of the surface of the absorber layer 14 containing Sn, and as well, to form an absorber pattern 141 (see FIG. 5) with high precision.

The reflective mask blank 10A may have the preventive layer 15 formed to contain one or more species of elements selected from among He, Ne, Ar, Kr, and Xe. There may be a case where when forming the preventive layer 15 as a film, use of these elements as the sputtering gas causes minute amounts of these elements to be contained in the preventive layer 15. Even in such a case, the properties of the preventive layer 15 are not affected, and the preventive layer 15 can exhibit its function.

The reflective mask blank 10A may have the preventive layer 15 to have a film thickness less than or equal to 10 nm. This enables to curb the film thickness of the preventive layer 15, and hence, the entire thickness of the reflective mask blank 10A, which is constituted with the absorber pattern 141 (see FIG. 5) and the pattern of the preventive layer 15 formed over the absorber pattern 141, can be curbed.

The reflective mask blank 10A may have the absorber layer 14 formed to contain one or more species of elements selected from among Ta, Cr, and Ti. Having these elements contained in the absorber layer 14 enables to further raise the cleaning resistance of the absorber layer 14, and thereby, enables to make the absorber layer 14 thinner. As a result, the absorber layer 14 having a high absorptivity of EUV light can be obtained even though made thinner. Thus, it is possible to lower the reflectance of the EUV light on the absorber layer 14 while attempting to make the reflective mask blank 10A as a thinner film and to make the pattern of the reflective mask 20 (see FIG. 5) as a thinner film.

In the reflective mask blank 10A, it is favorable to provide the protective layer 13 between the reflective layer 12 and the absorber layer 14. This enables, in the course of manufacturing the reflective mask 20 (see FIG. 5), to protect the reflective layer 12 when etching the absorber layer 14 or cleaning the reflective mask blank. Therefore, the reflectance of the obtained reflective mask 20 (see FIG. 5) with respect to EUV light can be made satisfactory.

<Method of Manufacturing Reflective Mask Blank>

Next, a method of manufacturing a reflective mask blank 10A illustrated in FIG. 1 will be described. FIG. 2 is a flowchart illustrating an example of a method of manufacturing a reflective mask blank 10A.

As illustrated in FIG. 2, a reflective layer 12 is formed over a substrate 11 (step of forming a reflective layer 12, Step S11). The reflective layer 12 is formed over the substrate 11 so as to have a desired film thickness by using a publicly known film-forming method as described above.

Next, a protective layer 13 is formed over the reflective layer 12 (step of forming a protective layer 13, Step S12). The protective layer 13 is formed over the reflective layer 12 so as to have a desired film thickness by using a publicly known film-forming method.

Next, an absorber layer 14 is formed over the protective layer 13 (step of forming an absorber layer 14, Step S13). The absorber layer 14 is formed over the protective layer 13 so as to have a desired film thickness by using a publicly known film-forming method. For example, the absorber layer 14 can be formed by using a publicly known film-forming device, in a film-forming chamber of the film-forming device.

Also, after having the absorber layer 14 formed, the mask blank in production may be taken out of the film-forming chamber of the film-forming device used for forming the absorber layer 14, transferred to a storage chamber, and then, the storage chamber is put into a high vacuum state to store the mask blank until the next use of it, for example, a step of forming a preventive layer 15 over the absorber layer 14.

Next, a preventive layer 15 is formed over the absorber layer 14 (step of forming a preventive layer 15, Step S14). The preventive layer 15 is formed over the absorber layer 14 in an inert gas atmosphere or in a gas atmosphere in which nitrogen is selectively added to an inert gas, so as to have a desired film thickness by using a publicly known film-forming method.

With these steps, a reflective mask blank 10A as illustrated in FIG. 1 is obtained.

Also, in the present embodiment, the method of manufacturing the reflective mask blank 10A allows the step of forming an absorber layer 14 (Step S13) and the step of forming a preventive layer 15 (Step S14) to be performed continuously. In this case, co-sputtering can be used that uses a target of a metal or the like to form the absorber layer 14 such as an Sn target, and a target of a metal or the like to form the preventive layer 15 such as a Ta target. By using co-sputtering and terminating charging of the target of the metal or the like to form the absorber layer 14 earlier than the charging of the target of the metal or the like to form the preventive layer 15, formation of the absorption layer 14 and formation of the preventive layer 15 can be performed continuously in a film-forming chamber of the film-forming device.

(Other Layers)

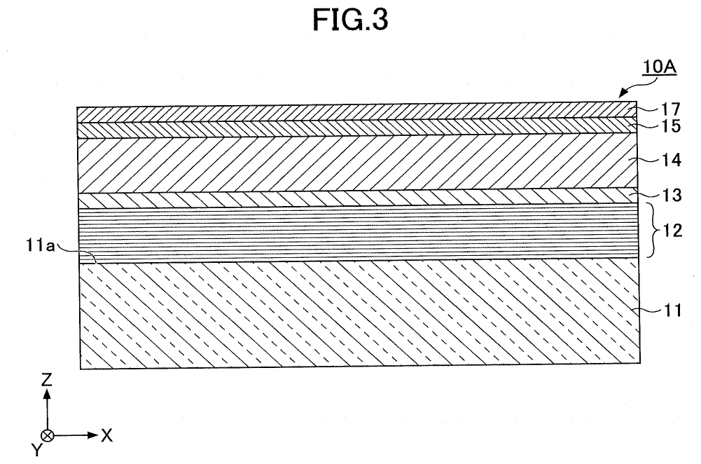

The reflective mask blank 10A may have a hard mask layer 17 provided over the preventive layer 15 as illustrated in FIG. 3. As the hard mask layer 17, a material that is highly resistant to etching is used, which may be a Cr-based film, Si-based film, Ru-based film, or the like.

As the material of a Cr-based film, for example, Cr and a material of Cr to which O or N is added may be used. Specifically, CrO, CrN, CrON, and the like may be listed.

As the material of an Si-based film, Si and a material of Si to which one or more species selected from among a group consisting of O, N, C, and H are added, may be listed. Specifically, SiO₂, SiON, SiN, SiO, Si, SiC, SiCO, SiCN, SiCON, and the like may be listed. Among these, an Si-based film is favorable because the sidewalls hardly retreat when the absorber layer 14 is dry-etched.

As the material of an Ru-based film, for example, Ru and a material of Ru to which O or N is added may be used. Specifically, RuO, RuN, RuON, and the like may be listed.

Forming the hard mask layer 17 over the preventive layer 15 enables to perform dry-etching even if the minimum line width of the absorber pattern 141 becomes smaller. Therefore, it is effective for finer microfabrication of the absorber pattern 141. Note that in the case of layering another layer over the preventive layer 15, the hard mask layer 17 may be provided on the topmost layer on the surface side of the preventive layer 15.

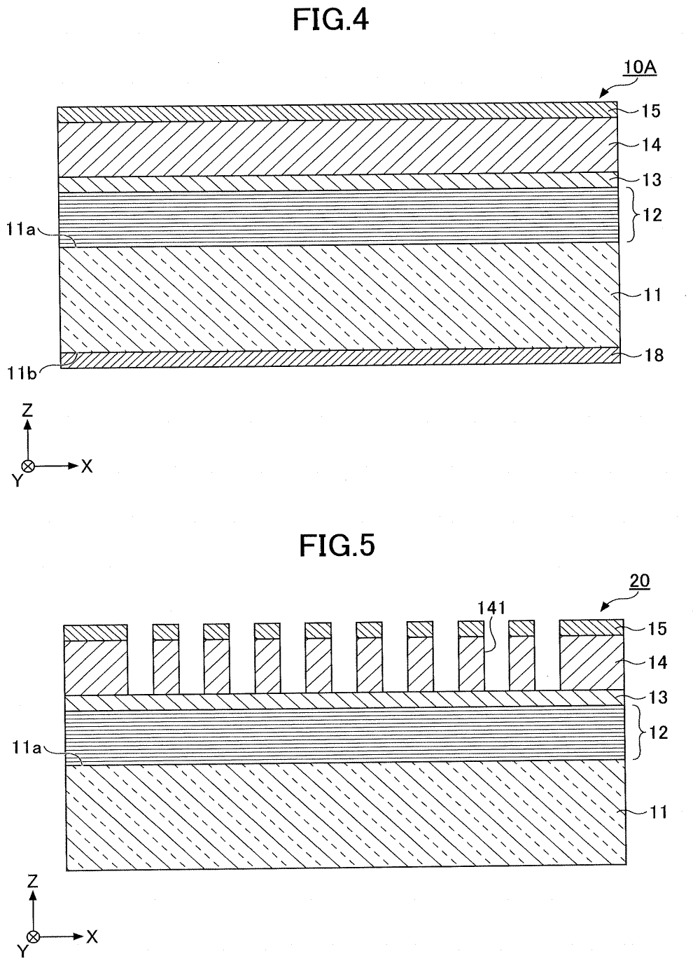

As illustrated in FIG. 4, the reflective mask blank 10A may have a backside conductive layer 18 provided for electrostatic chucking on a second principal surface 11b opposite to the side on which the reflective layer 12 of the substrate 11 is layered. The backside conductive layer 18 is required to have a low sheet resistance as a property. The sheet resistance of the backside conductive layer 18 is, for example, less than or equal to 250 Ω/sq, and favorably less than or equal to 200 Ω/sq.

As the material contained in the backside conductive layer 18, for example, a metal such as Cr or Ta or an alloy of these may be used. As an alloy containing Cr, a Cr compound containing, in addition to Cr, one or more species selected from among a group consisting of B, N, O, and C may be used. As a Cr compound, for example, CrN, CrON, CrCN, CrCON, CrBN, CrBON, CrBCN, CrBOCN, and the like may be listed. As an alloy containing Ta, a Ta compound containing, in addition to Ta, one or more species selected from among a group consisting of B, N, O, and C can be used. As a Ta compound, for example, TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, TaSiCON, and the like may be listed.

Although the film thickness of the backside conductive layer 18 is not limited in particular as long as the function expected as an electrostatic chuck can be fulfilled, the film thickness is set to, for example, 10 to 400 nm. In addition, the backside conductive layer 18 may also have a function of adjusting stress on the second principal surface 11b side of the reflective mask blank 10A. In other words, the backside conductive layer 18 can keep a balance with stress from the layers formed over the first principal surface 11a side so as to keep the reflective mask blank 10A flat.

As the method of forming the backside conductive layer 18, a publicly known film-forming method, such as magnetron sputtering or ion beam sputtering, may be used. The backside conductive layer 18 may be formed on the second principal surface 11b of the substrate 11, for example, before forming the protective layer 13.

<Reflective Mask>

Next, a reflective mask obtained by using a reflective mask blank 10A illustrated in FIG. 1 will be described. FIG. 5 is a schematic cross-sectional view illustrating an example of a configuration of a reflective mask 20. As illustrated in FIG. 5, the reflective mask 20 has a desired absorber pattern 141 formed in the absorber layer 14 of a reflective mask blank 10A illustrated in FIG. 1.

An example of a method of manufacturing the reflective mask 20 will be described. FIGS. 6A to 6C are diagrams illustrating a manufacturing process of the reflective mask 20. As illustrated in FIG. 6A, a resist layer 19 is formed over the absorber layer 14 of the reflective mask blank 10A illustrated in FIG. 1 described above.

Then, the resist layer 19 is exposed with a desired pattern. After the exposure, the exposed part of the resist layer 19 is developed and cleaned (rinsed) with pure water to form a desired resist pattern 191 in the resist layer 19 as illustrated in FIG. 6B.

Then, the resist layer 19 in which the resist pattern 191 has been formed is used as a mask to dry-etch the absorber layer 14. The etching forms, as illustrated in FIG. 6C, an absorber pattern 141 corresponding to the resist pattern 191 in the absorber layer 14.

As the etching gas, it is possible to use an F-based gas; a Cl-based gas; a mixture gas containing a Cl-based gas, O₂, and He or Ar by predetermined ratios; or the like.

Then, the resist layer 19 is removed by a resist stripping liquid or the like, to form a desired absorber pattern 141 in the absorber layer 14. Thus, as illustrated in FIG. 5, a reflective mask 20 having a desired absorber pattern 141 formed in the absorber layer 14 can be obtained.

The obtained reflective mask 20 is irradiated with EUV light by an illumination optical system of an exposure device. The EUV light incident on the reflective mask 20 is reflected on a part without the absorber layer 14 (part of the absorber pattern 141) and is absorbed on a part with the absorber layer 14. As a result, the reflected light of the EUV light reflected on the absorber layer 14 transmits through a reduction projection optical system of the exposure device, to have a material to be exposed (e.g., a wafer) irradiated with the light. This transfers the absorber pattern 141 of the absorber layer 14 onto the exposure material, to form a circuit pattern on the exposure material.

### Second Embodiment

A reflective mask blank according to a second embodiment will be described with reference to the drawings. Note that members having substantially the same functions as in the above embodiment are assigned the same reference codes, to omit detailed description.

FIG. 7 is a schematic cross-sectional view of a reflective mask blank according to the second embodiment. As illustrated in FIG. 7, a reflective mask blank 10B has a stabilizing layer 21 over the preventive layer 15 of the reflective mask blank 10A illustrated in FIG. 1. In other words, the reflective mask blank 10B is formed by layering over a substrate 11, a reflective layer 12, a protective layer 13, an absorber layer 14, the preventive layer 15, and the stabilizing layer 21 in this order.

As the stabilizing layer 21, an oxide, oxynitride, or oxyboride that contains Ta may be used. As such a oxide, oxynitride, or oxyboride that contains Ta, for example, TaO, Ta₂O₅, TaON, TaCON, TaBO, TaBON, TaBCON, TaHfO, TaHfON, TaHfCON, TaSiO, TaSiON, TaSiCON, or the like may be listed.

The film thickness of the stabilizing layer 21 is favorably less than or equal to 10 nm. The film thickness of the stabilizing layer 21 is more favorably less than or equal to 7 nm, furthermore favorably less than or equal to 6 nm, even more favorably less than or equal to 5 nm, and particularly favorably less than or equal to 4 nm. The film thickness of the stabilizing layer 21 is more favorably greater than or equal to 1 nm, furthermore favorably greater than or equal to 2 nm, and particularly favorably greater than or equal to 3 nm.

The stabilizing layer 21 can be formed by using a publicly known film-forming method such as magnetron sputtering or ion beam sputtering.

As such, in the reflective mask blank 10B, having the stabilizing layer 21 over the preventive layer 15 enables to further raise the cleaning resistance of the preventive layer 15. Having the stabilizing layer 21 enables to form a rigid and stable film with a good reproducibility, and to stabilize the properties of the reflective mask blank and the reflective mask.

Since the reflective mask blank 10B has the preventive layer 15 over the absorber layer 14 containing Sn, the surface of the absorber layer 14 does not come into contact with oxygen when forming the stabilizing layer 21 over the preventive layer 15. For example, in the case of forming the stabilizing layer 21 by using reactive sputtering, as described above, as the sputtering gas, a mixed gas in which oxygen is mixed in an inert gas such as He, Ar, Kr or the like; or a mixed gas in which nitrogen is selectively added and oxygen is further mixed in an inert gas is used. Since the preventive layer 15 has been formed over the absorber layer 14, when forming the stabilizing layer 21, the surface of the absorber layer 14 does not come into contact with the mixed gas as the sputtering gas. Therefore, the surface of the absorber layer 14 is not oxidized, and it is possible to prevent generation of deposits on the surface of the absorber layer 14.

Since the reflective mask blank 10B has the stabilizing layer 21 formed by using an oxide, oxynitride, or oxyboride that contains Ta, no change occurs in the composition of the stabilizing layer 21 by cleaning. Therefore, it is possible to obtain a reflective mask blank and a reflective mask that are excellent in the cleaning resistance.

Making the film thickness of the stabilizing layer 21 less than or equal to 10 nm enables to make the reflective mask blank 10B thinner, to make the reflective mask pattern thinner, and at the same time, to maintain the cleaning resistance of the preventive layer 15.

Note that as illustrated in FIG. 8, the reflective mask blank 10B may have a hard mask layer 17 provided over the stabilizing layer 21 as in the reflective mask blank 10A according to the first embodiment illustrated in FIG. 4.

### Application Examples

In the following, Example 1 is a comparative example, and Examples 2 to 4 are application examples.

### Example 1

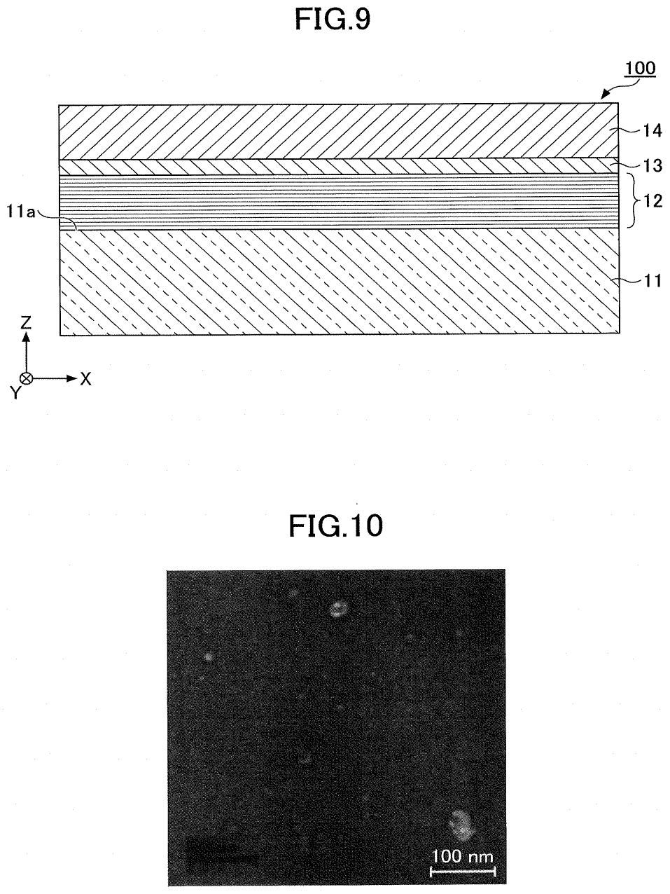

A reflective mask blank 100 is illustrated in FIG. 9. The reflective mask blank 100 is a reflective mask blank in which the preventive layer 15 over the absorber layer 14 is omitted in the reflective mask blank 10A according to the first embodiment illustrated in FIG. 1.

(Production of Reflective Mask Blank)

As the substrate for forming a film, an SiO₂—TiO₂-based glass substrate (having an external form of an approximately 152-mm square and a thickness of 6.3 mm) was used. Note that the thermal expansion coefficient of the glass substrate was less than or equal to 0.02×10⁻⁷/° C. The glass substrate was polished and processed to make the surface smooth so as to have a surface roughness of less than or equal to 0.15 nm by the root-mean-square roughness Rq and to have a flatness less than or equal to 100 nm. On the back surface of the glass substrate, a Cr layer having a film thickness of approximately 100 nm was formed by using magnetron sputtering, to form a backside conductive layer (conductive film) for electrostatic chucking. The sheet resistance of the Cr layer was approximately 100 Ω/sq. After having the glass substrate fixed by using the Cr film, on the surface of the glass substrate, an Si film and an Mo film were repeatedly formed for 40 cycles by using ion beam sputtering. The film thickness of the Si film was approximately 4.5 nm, and the film thickness of the Mo film was approximately 2.3 nm. In this way, a reflective layer (multilayer reflective film) having a total film thickness of approximately 272 nm ((4.5 nm of the Si film+2.3 nm of the Mo film)×40) was formed. Then, an Ru layer (film thickness of approximately 2.5 nm) was formed over the reflective layer by using ion beam sputtering, to form a protective layer (protective film). Next, over the protective layer, an absorber layer (absorber film) made of an Sn—Ta alloy and having a film thickness of 40 nm was formed by using magnetron sputtering. Ar gas was used as the sputtering gas. The target used for the sputtering contains 60 at % of Sn and 40 at % of Ta, whereas the Ta content in the sputtered absorber layer was 48 at %. Note that the content of Sn and the content of Ta in the absorber layer were measured by fluorescent X-ray spectroscopy (XRF) (Delta, manufactured by Olympus Corporation). In this way, the reflective mask blank 100 illustrated in FIG. 9 was produced. The film thickness of the absorber layer was measured by XRR by using an X-ray diffraction device (SmartLab HTP, manufactured by Rigaku Corporation). Note that the absorber layer made of the Sn—Ta alloy was confirmed to be amorphous from measurement results of X-ray diffraction (XRD) using the device.

(Observation of the Surface of the Reflective Mask Blank)

The surface of the reflective mask blank 100 was observed by using a scanning electron microscope (Ultra 60, manufactured by Carl Zeiss AG). An observation result of the surface of the reflective mask blank is illustrated in FIG. 10. As illustrated in FIG. 10, fine particles were observed on the surface of the reflective mask blank. The fine particles were analyzed by energy dispersive X-ray analysis (EDX), and as a result, it was confirmed that the fine particles were formed of a tin oxide. It can be considered that the fine particles on the surface of the absorber layer were generated from Sn contained in the absorber layer that was reacted with oxygen in the atmosphere when the absorber layer was exposed to the atmosphere. Such fine particles are not desirable because there may be a case where the particles remain as pattern defects on the reflective mask after the absorber layer has been etched.

### Example 2

In this example, a reflective mask blank 10A as illustrated in FIG. 1 was produced by forming a 4-nm-thick TaN film, which served as the preventive layer, over the absorber layer of the reflective mask blank 100 produced in Example 1. Note that the preventive layer was formed by using reactive sputtering, using a mixed gas of Ar and nitrogen as the sputtering gas, setting the flow rate of Ar to 70 sccm, and setting the flow rate of nitrogen to 2 sccm. Note that the reflective mask blank 100 produced in Example 1 had been transferred from a film-forming chamber to a storage chamber of a film-forming device used for forming the absorber layer, and the inside of the storage chamber had been put into a high vacuum state, to store the reflective mask blank 100 until the preventive layer was to be formed over the absorber layer.

(Observation of the Surface of the Reflective Mask Blank)

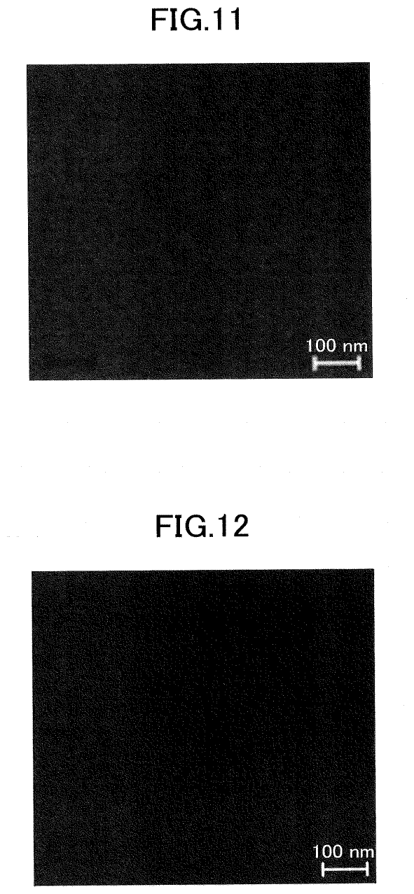

The surface of the reflective mask blank 10A was observed by using the scanning electron microscope. A result of observation of the surface of the absorber layer of the reflective mask blank 10A is illustrated in FIG. 11. As illustrated in FIG. 11, no fine particle was generated on the surface of the absorber layer of the reflective mask blank 10A. It is possible to state that this is because the presence of the preventive layer on the surface of the absorber layer prevented oxygen in the atmosphere from coming into contact with Sn contained in the absorber layer.

### Example 3

In this example, a 2-nm-thick Ta film as the preventive layer was formed over the absorber layer of the reflective mask blank 100 produced in Example 1, by using magnetron sputtering; and further, a 2-nm-thick TaO film as the stabilizing layer was formed over the preventive layer by using reactive sputtering. In this way, a reflective mask blank 10B illustrated in FIG. 7 was produced. Note that when the preventive layer was formed by using magnetron sputtering, Ar gas was used as the sputtering gas. When the stabilizing layer was formed by using reactive sputtering, a mixed gas of Ar and oxygen was used as the sputtering gas, and the flow rate of Ar was set to 40 sccm, and the flow rate of oxygen was set to 30 sccm. Note that the reflective mask blank 100 produced in Example 1 had been transferred from the film-forming chamber to the storage chamber of the film-forming device used for forming the absorber layer, and the inside of the storage chamber had been put into a high vacuum state, to store the reflective mask blank 100 until the preventive layer was to be formed over the absorber layer.

The formed preventive layer and stabilizing layer of the reflective mask blank 10B were measured by XRR, and as a result, the film thickness of Ta was 0.9 nm and the film thickness of TaO was 4.6 nm. It can be considered this is because when the TaO film was formed over the Ta film, oxygen contained in the sputtering gas reacted with Ta in the Ta film, to expand the TaO film.

Then, the reflective mask blank 10B illustrated in FIG. 7 was dry-etched by using a dry-etching device. Dry-etching was performed to remove the preventive layer and the stabilizing layer by using an F-based gas, and then, to remove the absorber layer by using a Cl-based gas.

(Observation of the Surface of the Reflective Mask Blank)

The surface of the reflective mask blank 10B was observed by using the scanning electron microscope. An observation result of the surface of the reflective mask blank 10B is illustrated in FIG. 12. As illustrated in FIG. 12, no deposits such as fine particles were observed on the surface of the reflective mask blank. In this example, only Ar was used as the sputtering gas when the preventive layer was formed. Therefore, the surface of the absorber layer was not exposed to an atmosphere containing oxygen, and hence, Sn present on the surface of the absorber layer did not react with oxygen. It is possible to state that this enabled to prevent generation of deposits on the surface of the absorber layer.

### Example 4

(Production of the Reflective Mask Blank)

In this example, when forming an absorber layer made of the Sn—Ta alloy, co-sputtering using an Sn target and a Ta target simultaneously was used, instead of an Sn—Ta alloy target as in Example 3. In addition, Ar gas was used as the sputtering gas; the flow rate of Ar was set to 70 sccm; the input power to the Sn target was set to 130 W; and the input power to the Ta target was set to 200 W. When the co-sputtering was performed, charging was started at the same time for the Sn target and for the Ta target. The end time of charging was set to 520 seconds after the start of charging for the Sn target and 608 seconds after the start of charging for the Ta target. This enabled to continuously form a 35-nm-thick absorber layer made of the Sn—Ta alloy and a 2-nm-thick preventive layer made of Ta over the absorber layer by a single sputtering operation. Then, a 2-nm-thick stabilizing layer made of TaO was formed over the preventive layer by using reactive sputtering as in Example 3. In this way, a reflective mask blank 10B illustrated in FIG. 7 was produced. Note that the Ta content in the sputtered absorber layer was 35% as measured by XRF.

(Observation of the Surface of the Reflective Mask Blank)

The surface of the reflective mask blank 10B produced in this example was observed by using the scanning electron microscope, and as a result, no deposit such as fine particles was observed on the surface of the reflective mask blank 10B. When forming the absorber layer and the preventive layer by two sputtering operations as in the case of Example 2 or Example 3, the reflective mask blank 100 produced to have the absorber layer formed in Example 1 needs to be returned from the film-forming chamber to the storage chamber of the film-forming device used for forming the absorber layer. Even though a high vacuum state is maintained in the storage chamber, there is a risk that a minute amount of residual oxygen may cause generation of fine particles of an oxide on the surface of the absorber film. In this example, since the absorber layer and the preventive layer were continuously formed in the film-forming chamber of the film-forming device to produce the reflective mask blank 10D, the risk of generation of fine particles of an oxide in the storage chamber could be reduced. Further, sputtering performed by the single operation enabled to shorten the production time of the reflective mask blank 10B.

As above, the embodiments have been described. Note that the embodiments described above are presented as examples, and the present invention is not limited by the embodiments described above. The embodiments described above can be implemented in various other forms, and various combinations, omissions, substitutions, changes, and the like can be made within a scope not deviating from the subject matters of the inventive concept. These embodiments and their variations are included in the scope and subject matters of the inventive concept, and are also included in the scope of the inventive concept described in the claims and equivalents thereof.

1. A reflective mask blank having a reflective layer to reflect EUV light and an absorber layer to absorb the EUV light, formed over a substrate in this order from a substrate side,
wherein the absorber layer contains Sn, and
wherein a preventive layer is provided over the absorber layer, to prevent oxidation of the absorber layer.

2. The reflective mask blank as claimed in claim 1, wherein the preventive layer contains one or more species of elements selected from among a group consisting of Ta, Ru, Cr, Ti and Si, and does not contain Sn and oxygen.

3. The reflective mask blank as claimed in claim 2, wherein the preventive layer contains one or more species of components selected from among a group consisting of Ta, Ru, Cr, Si, Ta nitride, Ru nitride, Cr nitride, Ti nitride, Si nitride, Ta boride, Ru boride, Cr boride, Ti boride, Si boride, and Ta boron nitride.

4. The reflective mask blank as claimed in claim 1, wherein the preventive layer contains one or more species of elements selected from among a group consisting of He, Ne, Ar, Kr, and Xe.

5. The reflective mask blank as claimed in claim 1, wherein a film thickness of the preventive layer is less than or equal to 10 nm.

6. The reflective mask blank as claimed in claim 1, wherein the absorber layer contains one or more species of elements selected from among a group consisting of Ta, Cr and Ti.

7. The reflective mask blank as claimed in claim 1, wherein a stabilizing layer is provided over the preventive layer.

8. The reflective mask blank as claimed in claim 7, wherein the stabilizing layer contains one or more species selected from among a group consisting of an oxide, an oxynitride, and an oxyboride each of which contains Ta.

9. The reflective mask blank as claimed in claim 7, wherein a film thickness of the stabilizing layer is less than or equal to 10 nm.

10. The reflective mask blank as claimed in claim 1, wherein a protective layer is provided between the reflective layer and the absorber layer.

11. The reflective mask blank as claimed in claim 1, wherein a hard mask layer is provided over the preventive layer or over a topmost layer on a surface side of the preventive layer.

12. The reflective mask blank as claimed in claim 11, wherein the hard mask layer contains at least one species of element selected from among a group consisting of Cr, Si, and Ru.

13. The reflective mask as claimed in claim 1, wherein a pattern is formed in the absorber layer of the reflective mask blank.

14. A method of manufacturing a reflective mask blank having a reflective layer to reflect EUV light and an absorber layer to absorb the EUV light formed over a substrate in this order from a substrate side, the method comprising:
forming the reflective layer over the substrate;
forming the absorber layer containing Sn over the reflective layer; and
forming a preventive layer over the absorber layer, to prevent oxidation of the absorber layer.

15. The method of manufacturing the reflective mask blank as claimed in claim 14, wherein the forming of the absorber layer and the forming of the preventive layer are performed continuously in a film-forming chamber by using co-sputtering.
